(19) United States
(12) Patent Application Publication
(10) Pub. No.: US 2019/0137578 A1
(43) Pub. Date: May 9, 2019

(54) MAGNETIC SENSOR

(71) Applicants: DENSO CORPORATION, Kariya-city (JP); TOHOKU UNIVERSITY, Sendai-shi (JP)

(72) Inventors: Takamoto FURUICHI, Kariya-city (JP); Kenichi AO, Kariya-city (JP); Yasuo ANDO, Sendai-city (JP); Mikihiko OOGANE, Sendai-city (JP); Takafumi NAKANO, Sendai-city (JP)

(21) Appl. No.: 16/233,602

(22) Filed: Dec. 27, 2018

Related U.S. Application Data
(63) Continuation of application No. PCT/JP2017/023983, filed on Jun. 29, 2017.

(30) Foreign Application Priority Data
Jul. 4, 2016 (JP) 2016-132536

(51) Int. Cl. G01R 33/09; H01L 43/08; H01L 43/10; G11B 5/39; G01R 33/00

(52) U.S. Cl. CPC G01R 33/093; H01L 43/08; H01L 43/10; G01R 33/0023; G11B 5/3906; G01R 33/091; G01R 33/098

(57) ABSTRACT

A magnetic sensor includes a substrate that has a main surface, a free layer that has a magnetic easy axis in an in-plane direction parallel to the main surface, an intermediate layer that is disposed between the substrate and the free layer, and a fixed layer that is disposed between the substrate and the intermediate layer. The fixed layer includes: a first ferromagnetic layer a magnetization direction of which is fixed in a first direction that is nonparallel to the main surface; a second ferromagnetic layer a magnetization direction of which is fixed in a second direction in which a component of a direction parallel to a normal line of the main surface is opposite to the first direction; and a nonmagnetic layer that is disposed between the first ferromagnetic layer and the second ferromagnetic layer.

### CROSS REFERENCE TO RELATED APPLICATIONS

The present application is a continuation application of International Patent Application No. PCT/JP2017/023983 filed on Jun. 29, 2017, which designated the U.S. and claims the benefit of priority from Japanese Patent Application No. 2016-132536 filed on Jul. 4, 2016. The entire disclosures of all of the above applications are incorporated herein by reference.

### TECHNICAL FIELD

The present disclosure relates to a magnetic sensor.

### BACKGROUND

A magnetic sensor that detects an external magnetic field using a magnetoresistive element is known. This type of magnetic sensor has a fixed layer (that is, a pinned layer or a magnetization fixed layer), a magnetization direction of which is fixed, a free layer (that is, a magnetization free layer), a magnetization direction of which changes according to an external magnetic field, and an intermediate layer disposed between the fixed layer and the free layer.

### SUMMARY

The present disclosure provides a magnetic sensor including: a substrate that has a main surface; a free layer that has a magnetic easy axis in an in-plane direction parallel to the main surface; a fixed layer; and an intermediate layer that is disposed between the intermediate layer and the fixed layer. The fixed layer includes: a first ferromagnetic layer a magnetization direction of which is fixed in a first direction that is nonparallel to the main surface; a second ferromagnetic layer a magnetization direction of which is fixed in a second direction in which a component of a direction parallel to a normal line of the main surface is opposite to the first direction; and a nonmagnetic layer that is disposed between the first ferromagnetic layer and the second ferromagnetic layer.

### BRIEF DESCRIPTION OF THE DRAWINGS

FIG. 1 is a perspective view for showing a schematic configuration of a magnetic sensor according to a first embodiment;

FIG. 2 is a perspective view for showing a schematic configuration of a magnetic sensor according to a second embodiment;

FIG. 3 is a perspective view for showing a schematic configuration of a magnetic sensor according to a third embodiment; and

FIG. 4 is a plan view for showing a schematic configuration of a magnetic sensor according to a fourth embodiment.

### DETAILED DESCRIPTION

In a magnetic sensor detecting an external magnetic field using a magnetoresistive element and having a fixed layer, a free layer and an intermediate layer between the fixed layer and the free layer, a leakage magnetic field from the fixed layer is likely to affect the free layer, resulting in a degradation of detection accuracy.

In an embodiment of the present disclosure, a magnetic sensor includes: a substrate that has a main surface; a free layer that has a magnetic easy axis in an in-plane direction parallel to the main surface; a fixed layer; and an intermediate layer that is disposed between the intermediate layer and the fixed layer. The fixed layer includes: a first ferromagnetic layer a magnetization direction of which is fixed in a first direction that is nonparallel to the main surface; a second ferromagnetic layer a magnetization direction of which is fixed in a second direction in which a component of a direction parallel to a normal line of the main surface is opposite to the first direction; and a nonmagnetic layer that is disposed between the first ferromagnetic layer and the second ferromagnetic layer.

In such a configuration, the fixed layer has a so-called laminated ferrimagnetic structure in which the nonmagnetic layer is disposed between the first ferromagnetic layer and the second ferromagnetic layer and in which of the magnetization directions, magnetic components parallel to the normal line of the main surface (that is, the orthogonal magnetization direction component) are opposite to each other between the first ferromagnetic layer and the second ferromagnetic layer. Therefore, leakage of the magnetic field from the fixed layer can be suppressed as much as possible. According to the above configuration, it is possible to satisfactorily suppress the degradation in the detection accuracy due to the leakage magnetic field.

Hereinafter, embodiments of the present disclosure will be described with reference to the drawings. In the following descriptions, the same or equivalent parts are designated with the same reference numerals in each of the embodiments.

### First Embodiment

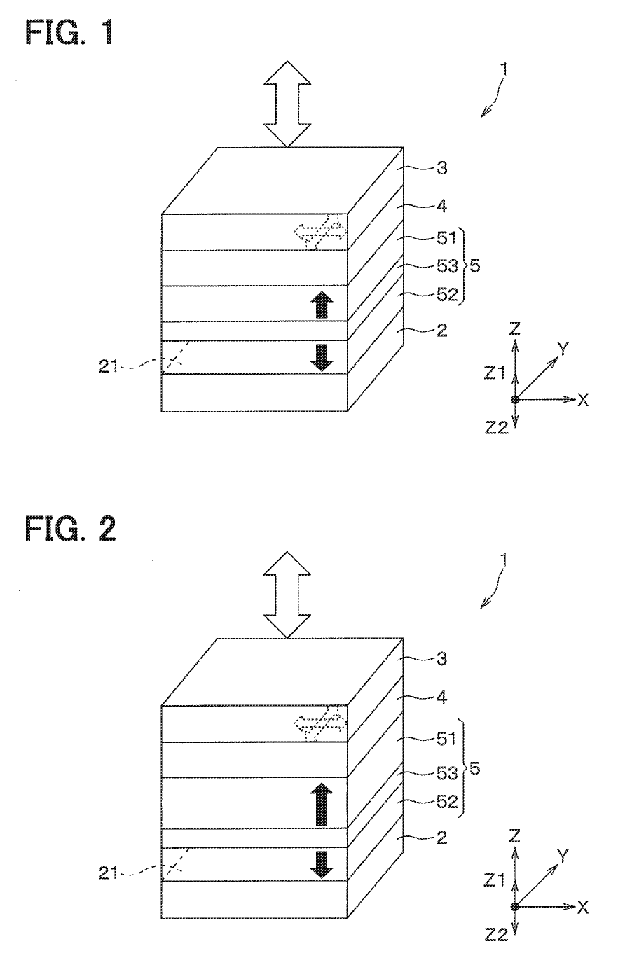

Referring to FIG. 1, a magnetic sensor 1 according to a first embodiment is a so-called magnetoresistive element, and includes a substrate 2, a free layer 3, an intermediate layer 4, and a fixed layer 5. The substrate 2 is a thin plate material having a uniform thickness, and is formed using, for example, a silicon wafer or the like. The substrate 2 has a main surface 21 that is a flat surface orthogonal to the thickness direction. The main surface 21 is provided in parallel to an XY plane in the figure. In this case, a Z-axis direction in the figure is a direction parallel to a normal line of the main surface 21, and will be hereinafter referred to as the “plane-orthogonal direction”. On the other hand, a direction parallel to the main surface 21 will be hereinafter referred to as the “in-plane direction”.

The free layer 3 is formed to have directions of a magnetic easy axis parallel to the in-plane direction, as shown by broken line arrows in the figure. The free layer 3 having such an in-plane magnetization can be formed, for example, using an alloy in an amorphous state containing at least one of Fe, Co and Ni, and B.

The intermediate layer 4, which is a nonmagnetic layer, is provided between the free layer 3 and the fixed layer 5. In the present embodiment, the intermediate layer 4 is provided between the substrate 2 and the free layer 3. The intermediate layer 4 is, for example, formed of an insulating material, such as MgO and AlO. In this case, the magnetic sensor 1 has a configuration as a tunneling magnetoresistive element. The tunneling magnetoresistive element is also called as a TMR element. TMR is abbreviation of Tunneling Magneto Resistance. Alternatively, the intermediate layer 4 may be formed of a conductor such as Cu and Ag. In this case, the magnetic sensor 1 has a configuration as a giant magnetoresistive element. The giant magnetoresistive element is also called as a GMR element. GMR is abbreviation of Giant Magneto Resistance.

The fixed layer 5 is disposed opposed to the free layer 3 with respect to the intermediate layer 4 interposed therebetween. Specifically, in the present embodiment, the fixed layer 5 is disposed between the substrate 2 and the intermediate layer 4. That is, the free layer 3, the intermediate layer 4, the fixed layer 5, and the substrate 2 are stacked in this order in the plane-orthogonal direction. In the present embodiment, the fixed layer 5 is configured to have a magnetization direction as a whole in the plane-orthogonal direction. In other words, the fixed layer 5 is configured to function as an orthogonal magnetization film in an operation of detecting an external magnetic field. Specifically, the fixed layer 5 has a first ferromagnetic layer 51, a second ferromagnetic layer 52, and a nonmagnetic layer 53.

The first ferromagnetic layer 51 is a ferromagnetic material film, a magnetization direction of which is fixed in a direction nonparallel to the main surface 21. Specifically, in the present embodiment, the first ferromagnetic layer 51 has the magnetization direction in a Z1 direction (that is, a positive direction along the Z axis) in the figure, which is parallel to the plane-orthogonal direction, as shown by a solid arrow in the figure. The first ferromagnetic layer 51 is thus a so-called orthogonal magnetization film. The first ferromagnetic layer 51 can be formed using a known thin film exemplified as: Co/Pt multilayer film; Co/Pd multilayer film; a thin film obtained by adding Pt, Ta, B, Nb or the like to a CoCr alloy; laminate magnetic film of Co/(Pt or Pd) multilayer film and Co—Xa/(Pt or Pd) multilayer film; laminate magnetic film of Co/(Pt or Pd) multilayer film and Co/{(Pt—Ya) or (Pd—Ya)} multilayered film layer (in which Ya is B, Ta, Ru, Re, Ir, Mn, Mg, Zr, or Nb); laminate magnetic film of CoCr alloy film and Co/(Pt or Pd) multilayer film; FePt alloy; and CoPt alloy.

The second ferromagnetic layer 52 is a ferromagnetic film, a magnetization direction of which is fixed in a direction nonparallel to the main surface 21. The magnetization direction of the second ferromagnetic layer 52 is provided so that the component in the plane-orthogonal direction of the magnetization direction of the second ferromagnetic layer 52 is opposite to the component in the plane-orthogonal direction of the magnetization direction of the first ferromagnetic layer 51. Specifically, in the present embodiment, the second ferromagnetic layer 52 has a magnetization direction in a Z2 direction (that is, a negative direction along the Z axis) in the figure, which is antiparallel to the magnetization direction of the first ferromagnetic layer 51, as shown by a solid arrow in the figure. The second ferromagnetic layer 52 is thus a so-called orthogonal magnetization film. The second ferromagnetic layer 52 can be formed using, for example, a known thin film exemplified above.

The nonmagnetic layer 53 is a thin film formed of a nonmagnetic material such as Ru, and is disposed between the first ferromagnetic layer 51 and the second ferromagnetic layer 52. That is, the fixed layer 5 has a so-called laminated ferrimagnetic structure in which the nonmagnetic layer 53 is interposed between the first ferromagnetic layer 51 and the second ferromagnetic layer 52 whose magnetization directions are antiparallel. In the present embodiment, the fixed layer 5 is configured so that the difference in magnetization amount between the first ferromagnetic layer 51 and the second ferromagnetic layer 52 is substantially zero. Specifically, in the present embodiment, the first ferromagnetic layer 51 and the second ferromagnetic layer 52 are formed of the same material and have the same thickness.

In FIG. 1, a main configuration as a so-called magnetoresistive element is shown. That is, details (for example, a wiring portion, a protective layer, an underlayer, and the like) necessary for an actual device configuration such as a TMR element are not shown in FIG. 1. The same applies to the other embodiments shown in FIG. 2 and the subsequent figures.

In the configuration of the present embodiment, the free layer 3 having the in-plane magnetization is provided. As indicated by a solid-line hollow arrow in the figure, magnetization reversal of the free layer 3 is moderate when detecting the external magnetic field in the plane-orthogonal direction, which is a direction of a magnetic hard axis of the free layer 3. Therefore, according to the configuration of the present embodiment, it is possible to detect the magnetic field strength in a wide magnetic field range. The fixed layer 5 has a laminated ferrimagnetic structure in which the nonmagnetic layer 53 is interposed between the first ferromagnetic layer 51 and the second ferromagnetic layer 52 whose magnetization components in orthogonal direction are opposite to each other. Therefore, leakage of the magnetic field from the fixed layer 5 can be suppressed as much as possible. That is, it is possible to satisfactorily suppress deterioration in the detection accuracy due to the leakage magnetic field from the fixed layer 5. As such, according to the configuration of the present embodiment, it is possible to detect the magnetic field intensity with favorable accuracy in a wide magnetic field range. Furthermore, in the configuration of the present embodiment, the fixed layer 5 is formed adjacent to the substrate 2. According to such a configuration, the crystallinity of the substrate 2 is easily reflected to the fixed layer 5. Therefore, according to such a configuration, the crystallinity of the fixed layer 5 is improved, and hence the magnetization characteristics of the fixed layer 5 is improved.

### Second Embodiment

Referring to FIG. 2, the configuration of a magnetic sensor 1 according to a second embodiment is different from the first embodiment on the point that the difference in magnetization amount between the first ferromagnetic layer 51 and the second ferromagnetic layer 52 is not substantially zero. Specifically, in the present embodiment, the first ferromagnetic layer 51 and the second ferromagnetic layer 52 are formed of the same material. However, the first ferromagnetic layer 51 and the second ferromagnetic layer 52 are formed to have different thicknesses. In the example of FIG. 2, the first ferromagnetic layer 51 is positioned closer to the intermediate layer 4 than the non-magnetic material layer 53 and is magnetized in the Z1 direction, and the second ferromagnetic layer 52 is positioned opposite to the intermediate layer 4 with respect to the nonmagnetic layer 53 and is magnetized in the Z2 direction. The first ferromagnetic layer 51 is thicker than the second ferromagnetic layer 52. That is, the magnetization amount of the first ferromagnetic layer 51 adjacent to the intermediate layer 4 is larger than that of the second ferromagnetic layer 52. Therefore, the magnetization amount of the fixed layer 5 as a whole in the plane-orthogonal direction is not zero, but is a predetermined amount in the Z1 direction. The other configurations of the magnetic sensor 1 according to the second embodiment are similar to those of the first embodiment. Therefore, in the following descriptions, the similar configurations and advantageous effects to those of the first embodiment will not be repeated.

Also in such a configuration, since the fixed layer 5 has the laminated ferrimagnetic structure, the deterioration in the detection accuracy due to the leakage magnetic field from the fixed layer 5 can be satisfactorily suppressed. Therefore, according to the configuration of the present embodiment, it is possible to detect the magnetic field intensity with favorable accuracy in a wide magnetic field range. In addition, the fixed layer 5 is configured so that the magnetization amount as a whole of the fixed layer 5 (that is, a vectorial addition of the magnetization amount of the first ferromagnetic layer 51 and the magnetization amount of the second ferromagnetic layer 52) has a predetermined value that is not substantially zero. Therefore, it is possible to easily realize a configuration (for example, a structure described in a fourth embodiment described later), in which a bridge circuit in which a plurality of magnetoresistive elements are connected is formed on the same substrate 2, by a simple manufacturing process.

### Third Embodiment

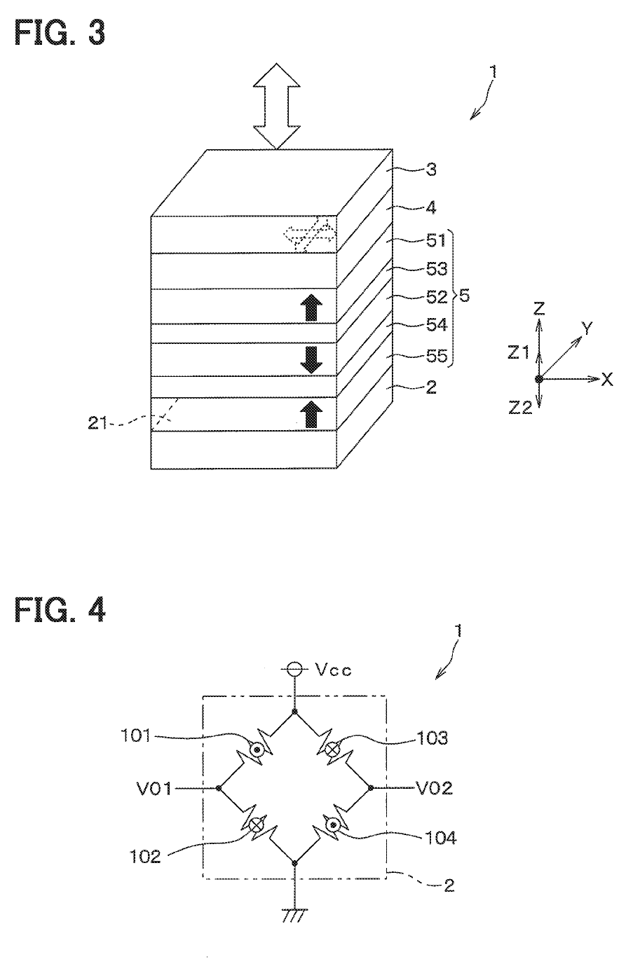

Referring to FIG. 3, a magnetic sensor 1 according to a third embodiment has similar configurations to the first and second embodiments except for the number of layers of the fixed layer 5. Therefore, in the following descriptions, the similar configurations and advantageous effects to those of the first embodiment and the second embodiment will not be repeated.

In addition to the first ferromagnetic layer 51, the second ferromagnetic layer 52, and the nonmagnetic layer 53, the fixed layer 5 of the magnetic sensor 1 according to the third embodiment further includes a nonmagnetic layer 54 and a third ferromagnetic layer 55. The nonmagnetic layer 54 is disposed opposite to the nonmagnetic layer 53 with respect to the second ferromagnetic layer 52. The third ferromagnetic layer 55 is disposed between the substrate 2 and the nonmagnetic layer 53.

The third ferromagnetic layer 55 is a ferromagnetic film, a magnetization direction of which is fixed in a direction nonparallel to the main surface 21. The magnetization direction of the third ferromagnetic layer 55 is provided such that the components in the plane-orthogonal direction of the magnetization direction of the third ferromagnetic layer 55 is opposite to the components in the plane-orthogonal direction of the magnetization direction of the second ferromagnetic layer 52. Specifically, in the present embodiment, the third ferromagnetic layer 55 has a magnetization direction in the Z1 direction that is antiparallel to the magnetization direction of the second ferromagnetic layer 52, as indicated by a solid arrow in the figure, and is a so-called orthogonal magnetization film. The third ferromagnetic layer 55 can be formed by using, for example, a known thin film exemplified above.

As described above, in the present embodiment, the fixed layer 5 has a so-called multilayer laminated ferrimagnetic structure. The magnetization amounts of the first ferromagnetic layer 51, the second ferromagnetic layer 52, and the third ferromagnetic layer 55 can be appropriately adjusted by parameters such as a material, a film thickness, and the like. Accordingly, it is possible to stably realize the configuration in which the magnetization amount as a whole of the fixed layer 5 is substantially zero as shown in FIG. 1 and the configuration in which the magnetization amount as a whole of the fixed layer 5 is not substantially zero as shown in FIG. 2. That is, according to the configuration of the present embodiment, the robustness against variations in film thickness of each layer and/or variations in composition of each layer at the time of manufacturing is improved.

### Fourth Embodiment

Referring to FIG. 4, the magnetic sensor 1 according to the fourth embodiment includes a first element 101, a second element 102, a third element 103, and a fourth element 104. The first element 101 is a magnetoresistive element having the similar configuration to the magnetic sensor 1 of the second embodiment shown in FIG. 2. That is, the first element 101 includes the substrate 2, the free layer 3, the intermediate layer 4, and the fixed layer 5 shown in FIG. 2.

The second element 102 is a magnetoresistive element having a similar configuration to the magnetic sensor 1 of the second embodiment, but the magnetization direction as a whole of the fixed layer 5 is reversed from that in the magnetic sensor 1 of the second embodiment shown in FIG. 2. Hereinafter, in the descriptions of the present embodiment, the magnetization direction of the fixed layer 5 as a whole is different between the first element 101 and the second element 102, with reference to FIG. 2 and FIG. 4. Specifically, in the present embodiment, the thickness of the first ferromagnetic layer 51 is the same between the first element 101 and the second element 102, but the magnetization direction of the first ferromagnetic layer 51 is opposite between the first element 101 and the second element 102. Similarly, the thickness of the second ferromagnetic layer 52 is the same between the first element 101 and the second element 102, but the magnetization direction of the second ferromagnetic layer 52 is opposite between the first element 101 and the second element 102. In the first element 101 and the fourth element 104, since the first ferromagnetic layer 51 magnetized in the Z1 direction is thicker than the second ferromagnetic layer 52 magnetized in the Z2 direction. Therefore, the magnetization direction of the fixed layer 5 as a whole is the Z1 direction. On the other hand, in the second element 102 and the third element 103, the first ferromagnetic layer 51 magnetized in the Z2 direction is thicker than the second ferromagnetic layer 52 magnetized in the Z1 direction. Therefore, the magnetization direction of the fixed layer 5 as a whole is the Z2 direction.

The third element 103 is a magnetoresistive element having the similar configuration to the second element 102. That is, the magnetization direction of the fixed layer 5 as a whole is the same between the second element 102 and the third element 103. Specifically, in the present embodiment, the thickness and the magnetization direction of the first ferromagnetic layer 51 are the same between the second element 102 and the third element 103. The same applies to the second ferromagnetic layer 52. The fourth element 104 is a magnetoresistive element having the similar configuration to the first element 101. That is, the magnetization direction of the fixed layer 5 as a whole is the same between the first element 101 and the fourth element 104.

The first element 101, the second element 102, the third element 103, and the fourth element 104 are formed on the same substrate 2. That is, in the present embodiment, a plurality of magnetoresistive elements, each having the free layer 3, the intermediate layer 4 and the fixed layer 5 shown in FIG. 2, are provided on the substrate 2.

The first element 101 and the second element 102 are connected in series between power supply voltage terminals. The third element 103 and the fourth element 104 are connected in series between the power supply voltage terminals. The series connection unit of the first element 101 and the second element 102 and the series connection unit of the third element 103 and the fourth element 104 are connected in parallel between the power supply voltage terminals. That is, a so-called full bridge circuit or a Wheatstone bridge circuit is formed by the first element 101, the second element 102, the third element 103, and the fourth element 104.

The magnetic sensor 1 having such a configuration detects a magnetic field based on a potential difference between the terminal potential V01 at the connection portion between the first element 101 and the second element 102 and the terminal potential V02 at the connection portion between the third element 103 and the fourth element 104. According to the magnetic sensor 1 having such a configuration, the influence of disturbance (for example, temperature) at the time of detecting a magnetic field can be suppressed as much as possible.

The magnetic sensor 1 having such a configuration can be satisfactorily realized on a single substrate 2 by appropriately adjusting known production conditions including film formation conditions and magnetization conditions. That is, the magnetic sensor 1 having the configuration shown in FIG. 4 can be manufactured stably using a simple film formation process and magnetization process.

(Modifications)

The present disclosure is not limited to the embodiments described hereinabove, but may be appropriately modified. Representative modifications will be described hereinafter. In the following descriptions of the modifications, only parts different from the above-described embodiments will be described. Therefore, in the following description of the modifications, regarding components having the same reference numerals as the components of the above-described embodiments, the descriptions in the above-described embodiment can be appropriately cited unless there is a technical inconsistency.

The substrate 2 may have a single layer structure or a multilayer structure. The free layer 3 may have a single layer structure or a multilayer structure. The intermediate layer 4 may have a single layer structure or a multilayer structure. Each layer constituting the fixed layer 5 may have a single layer structure or a multilayer structure. Although partly overlapping with the above description, any layer may be disposed on the free layer 3, between the free layer 3 and the intermediate layer 4, between the intermediate layer 4 and the fixed layer 5, or between the fixed layer 5 and the substrate 2. The material of each layer constituting the magnetic sensor 1 is not limited to the above example.

The configurations of the first ferromagnetic layer 51 and the like, which constitute the fixed layer 5, are not limited to the specific modes indicated in the above-described embodiments. For example, in FIG. 2, the second ferromagnetic layer 52 may be thicker than the first ferromagnetic layer 51. The material forming the first ferromagnetic layer 51 and the material forming the second ferromagnetic layer 52 may be the same or different. Similarly, the material forming the first ferromagnetic layer 51 and the third ferromagnetic layer 55 may be the same or different. That is, the amount of magnetization of the fixed layer 5 as a whole in the plane-orthogonal direction can be appropriately set depending on the amount of magnetization per unit dimension of each layer and the size of each layer.

Specifically, in the examples of FIGS. 1 and 2, it is assumed that the first ferromagnetic layer 51 and the second ferromagnetic layer 52 have the same sectional area in the in-plane direction. Under this condition, the magnetization amount per unit thickness of the first ferromagnetic layer 51 is defined as Ms1, and the thickness of the first ferromagnetic layer 51 is defined as t1. Likewise, the amount of magnetization per unit thickness of the second ferromagnetic layer 52 is defined as Ms2, and the thickness of the second ferromagnetic layer 51 is defined as t2. Note that each of the Ms1 and Ms2 has a positive value when the magnetization direction is Z1, and has a negative value when the magnetization direction is Z2. The absolute values of Ms1 and Ms2 can be set appropriately according to the selection of materials and the like. In this case, the magnetization amount Ms in the Z1 direction of the fixed layer 5 is obtained by the following equation. That is, when the value of Ms is negative, the absolute value is −Ms and the magnetization direction is Z2 as the magnetization state of the fixed layer 5 as a whole. In the first embodiment, the material and the thickness of each layer are appropriately set so that the value of Ms is substantially zero. In the second embodiment, the material and the thickness of each layer are appropriately set so that the Ms has a predetermined positive or negative value.

Ms=Ms1×t1+Ms2×t2

Therefore, for example, in the configuration of FIG. 2, when the first ferromagnetic layer 51 has the thickness t1 satisfying t1=ta, the magnetization amount Ms1 satisfying Ms1>0, and the second ferromagnetic layer 52 has the thickness t2 satisfying t2=tb (where ta>tb), and the magnetization amounts satisfies Ms2=−Ms1, the fixed layer 5 has the magnetization direction in the Z1 direction. On the other hand, when these conditions, that is, the thickness t1 of the first ferromagnetic layer 51 and the thickness t2 of the second ferromagnetic layer 52 are changed to satisfy t1=tb and t2=ta, the fixed layer 5 has the magnetization direction in the Z2 direction. In this way, it is possible to prepare two types of elements for the bridge circuit in which the magnetization amount is the same and the magnetization direction of the fixed layer 5 is inverted. In the configuration of FIG. 2, in a case where the thickness of the second ferromagnetic layer 52 is larger than that of the first ferromagnetic layer 51 (that is, t1<t2), and the fixed layer 5 is magnetized such that the first ferromagnetic layer 51 has the magnetization direction in the Z1 direction and the second ferromagnetic layer 52 has the magnetization direction in the Z2 direction, the fixed layer 5 is formed to have the magnetization direction in the Z2 direction as a whole. Further, in the configuration of FIG. 1 (that is, t1=t2), when the absolute value Ms1 and the absolute value Ms2 have a difference, the magnetization direction of the fixed layer 5 as a whole can be arbitrarily set.

The formation of the laminated ferrimagnetic structure using the orthogonal magnetization films is already well known at the time of the filing of this application. Therefore, a well-known method can be used as the magnetization method for magnetizing each layer of the fixed layer 5 in a predetermined direction.

The fixed layer 5 may be provided on an outer side (that is, adjacent to the external magnetic field) than the free layer 3. That is, the substrate 2, the free layer 3, the intermediate layer 4, and the fixed layer 5 may be stacked in the plane-orthogonal direction in this order. When the free layer 3 is disposed adjacent to the substrate 2, the crystallinity of the substrate 2 is easily reflected to the free layer 3. Therefore, in this case, the crystallinity of the free layer 3 is improved and thus the magnetic properties of the free layer 3 are improved.

The third element 103 and the fourth element 104 in FIG. 4 can be omitted. That is, the magnetic sensor 1 may be a half bridge circuit having a plurality of magnetoresistive elements.

In configuring the bridge circuit described above, the magnetization directions of the layers constituting the fixed layer 5 may be opposite to each other between the first element 101 and the second element 102. That is, the magnetization directions of the first ferromagnetic layer 51 and the second ferromagnetic layer 52 in the first element 101 may be the Z1 and Z2 directions, respectively, while the magnetization directions of the first ferromagnetic layer 51 and the second ferromagnetic layer 52 in the second element 102 may be the Z2 and Z1 directions, respectively.

The bridge circuit described above can also be realized by the magnetoresistive element having the configuration shown in FIG. 3.

The modifications are not limited to the above-described examples. The modifications may be combined with each other. Furthermore, all or a part of the above-described embodiments and all or a part of the modifications may be combined with each other.

What is claimed is:

1. A magnetic sensor comprising:
a substrate having a main surface;
a free layer having a magnetic easy axis in an in-plane direction that is parallel to the main surface;
a fixed layer including
a first ferromagnetic layer a magnetization direction of which is fixed in a first direction that is nonparallel to the main surface,
a second ferromagnetic layer a magnetization direction of which is fixed in a second direction in which a component in a plane-orthogonal direction parallel to a normal line of the main surface is opposite to the first direction, and
a nonmagnetic layer disposed between the first ferromagnetic layer and the second ferromagnetic layer; and
an intermediate layer disposed between the free layer and the fixed layer, wherein
the fixed layer is configured such that a vectorial addition of a magnetization amount as a whole in the plane-orthogonal direction is not substantially zero.

2. The magnetic sensor according to claim 1, wherein the second direction is antiparallel to the first direction.

3. The magnetic sensor according to claim 1, wherein the first direction is parallel to the normal line of the main surface.

4. The magnetic sensor according to claim 1, wherein a difference in magnetization amount between the first ferromagnetic layer and the second ferromagnetic layer is substantially zero.

5. The magnetic sensor according to claim 1, wherein a difference in magnetization amount between the first ferromagnetic layer and the second ferromagnetic layer is not substantially zero.

6. The magnetic sensor according to claim 1, wherein
the substrate is provided with a plurality of elements each having the free layer, the intermediate layer and the fixed layer,
the plurality of elements includes a first element and a second element, and
the magnetization direction of the fixed layer of the first element and the magnetization direction of the fixed layer of the second element are different.

7. The magnetic sensor according to claim 6, wherein the plurality of elements is configured to form a bridge circuit.
